(19) United States
(12) Patent Application Publication
(10) Pub. No.: US 2017/0092607 A1
(43) Pub. Date: Mar. 30, 2017

(54) CHIP PACKAGE AND METHOD FOR FORMING THE SAME

(71) Applicant: XINTEC INC., Taoyuan City (TW)

(72) Inventors: Hsin KUAN, Zhubei City (TW); Tsang-Yu LIU, Zhubei City (TW); Po-Han LEE, Taipei City (TW)

(21) Appl. No.: 15/272,297

(22) Filed: Sep. 21, 2016

Related U.S. Application Data
(60) Provisional application No. 62/233,067, filed on Sep. 25, 2015.

(51) Int. Cl. H01L 23/00; H01L 21/78

(52) U.S. Cl. CPC H01L 24/09; H01L 21/78; H01L 2224/48091; H01L 2224/04042; H01L 2224/05022

(57) ABSTRACT

A chip package is provided. The chip package includes a first substrate including a sensing region or device region. The chip package also includes a second substrate. The first substrate is mounted on the second substrate and is electrically connected to the second substrate. The ratio of the thickness of the first substrate to the thickness of the second substrate is in a range from 2 to 8.

### CROSS REFERENCE TO RELATED APPLICATIONS

This Application claims priority of U.S. Provisional Application No. 62/233,067, filed Sep. 25, 2015, the entirety of which is incorporated by reference herein.

### BACKGROUND OF THE INVENTION

Field of the Invention

The invention relates to chip package technology, and in particular to a thinned chip package and methods for forming the same.

Description of the Related Art

The chip packaging process is an important step in the fabrication of an electronic product. Chip packages not only protect the chips therein from outer environmental contaminants, but they also provide electrical connection paths between electronic elements inside and those outside of the chip packages.

The fabrication of a chip package comprises bonding a chip on a circuit board. However, the chip is picked up and pressed during the bonding process. Accordingly, the chip needs to have sufficient thickness to prevent the chip from being physically damaged. For example, there would be cracks in the chip if the chip is not thick enough. As a result, it is difficult to decrease the size of the chip package further.

Thus, there exists a need in the art for development of a chip package and methods for forming the same capable of mitigating or eliminating the aforementioned problems.

### BRIEF SUMMARY OF THE INVENTION

An embodiment of the invention provides a chip package. The chip package includes a first substrate including a sensing region or device region. The chip package also includes a second substrate. The first substrate is mounted on the second substrate and is electrically connected to the second substrate. The ratio of the thickness of the first substrate to the thickness of the second substrate is in a range from 2 to 8.

An embodiment of the invention provides a method for forming a chip package. The method includes providing a first substrate comprising a sensing region or device region. The method also includes mounting the first substrate onto a second substrate. The first substrate is electrically connected to the second substrate. The ratio of the thickness of the first substrate to the thickness of the second substrate is in a range from 2 to 8.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1F are cross-sectional views of some exemplary embodiments of a method for forming a chip package according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed. Furthermore, when a first layer is referred to as being on or overlying a second layer, the first layer may be in direct contact with the second layer, or spaced apart from the second layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, microfluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint-recognition devices, microactuators, surface acoustic wave devices, pressure sensors, ink printer heads, and so on.

The aforementioned wafer-level packaging process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level packaging process. In addition, the aforementioned wafer-level packaging process may also be adapted to form a chip package having multilayer integrated circuit devices by stacking a plurality of wafers having integrated circuits or to form a system-in-package (SIP).

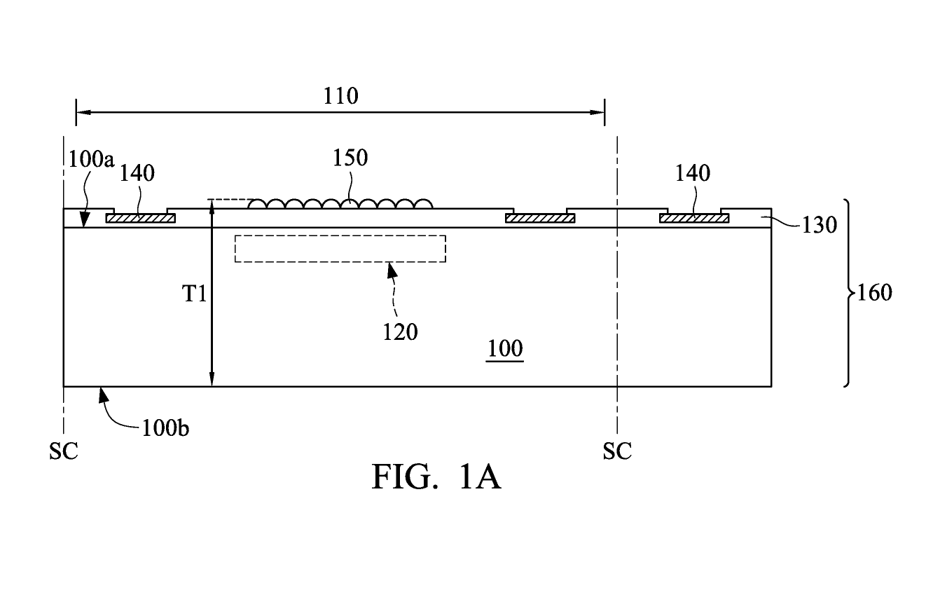

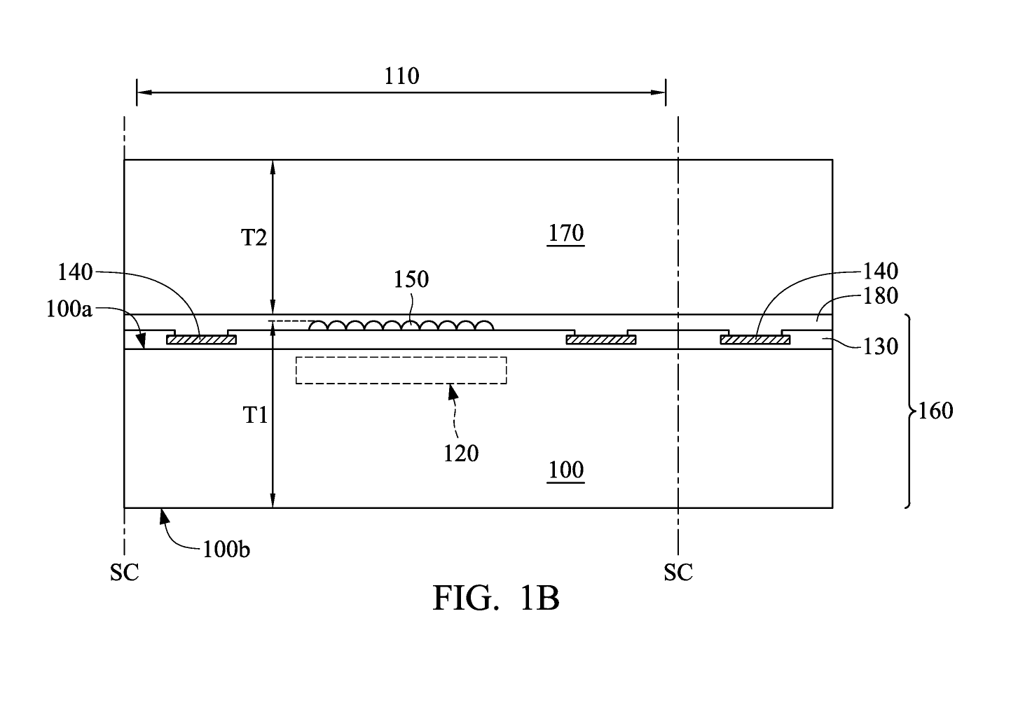

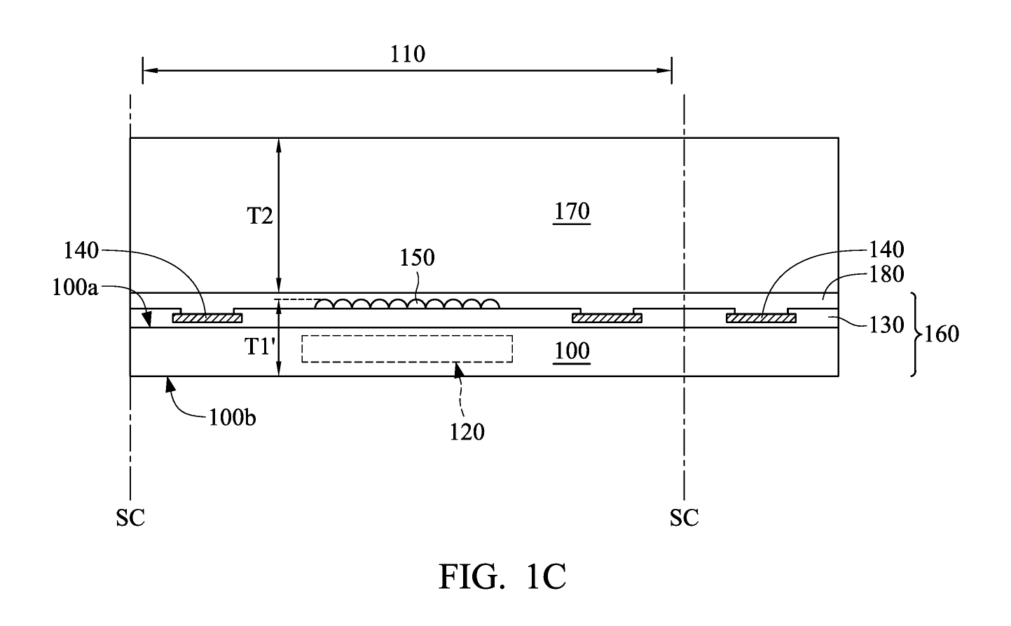

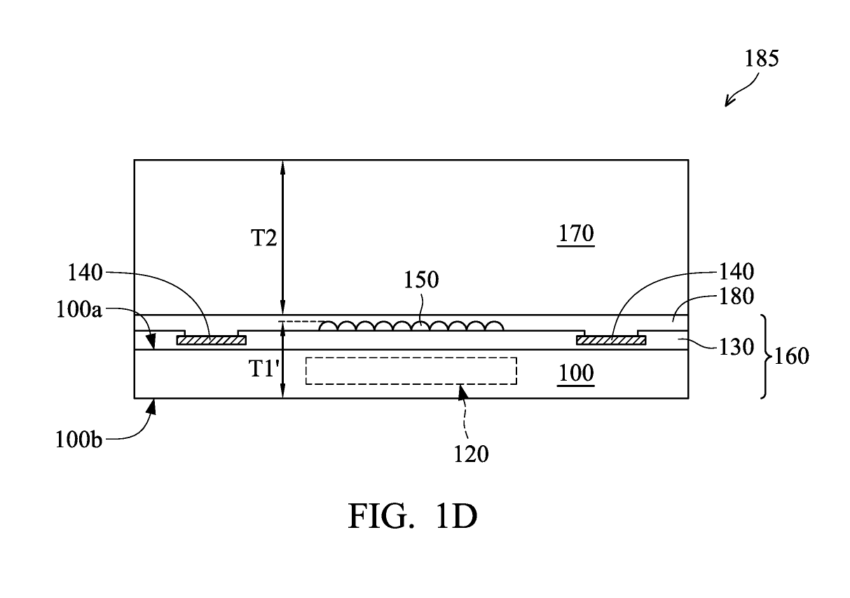

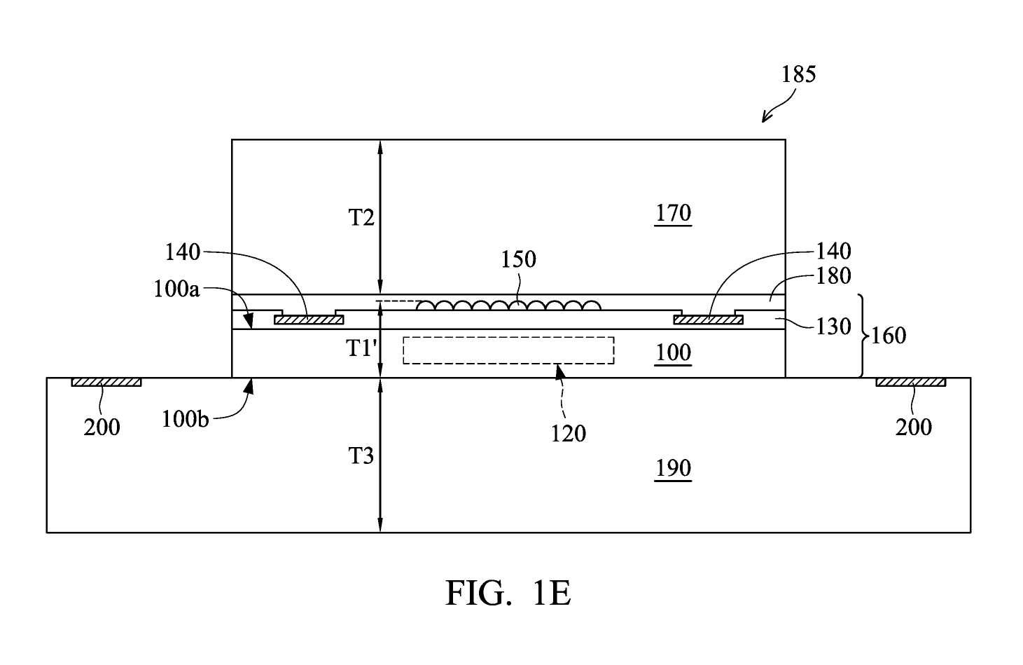

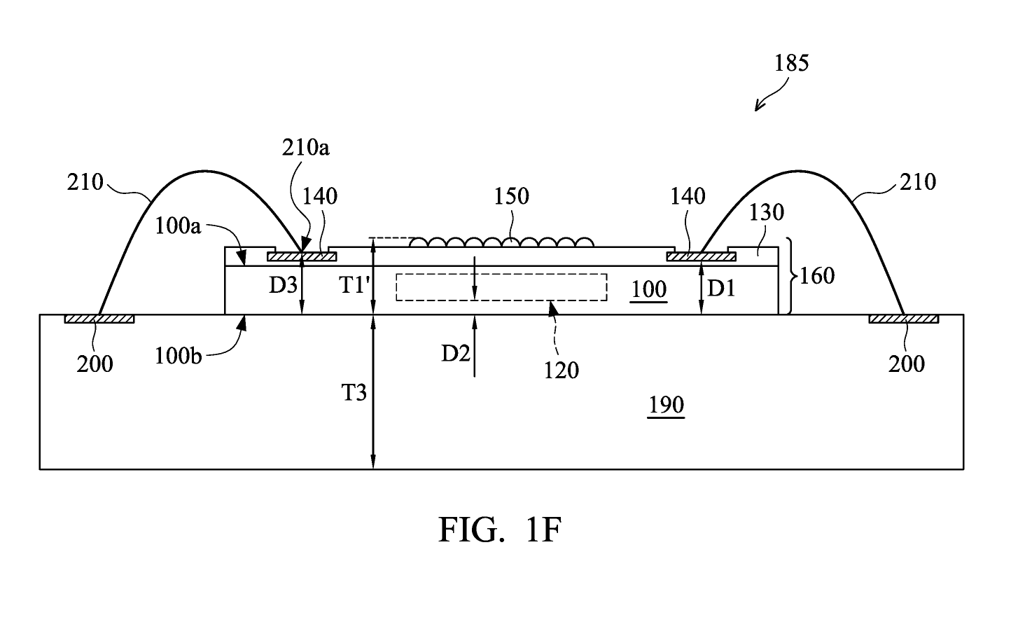

Some exemplary embodiments of a method for forming a chip package according to the invention are illustrated in FIGS. 1A to 1F. FIGS. 1A to 1F are cross-sectional views of some exemplary embodiments of a method for forming a chip package according to the invention.

Referring to FIG. 1A, a semiconductor substrate 100 is provided. The semiconductor substrate 100 has a first surface 100a and a second surface 100b opposite thereto. The semiconductor substrate 100 comprises multiple chip regions 110. To simplify the diagram, only a complete chip region and a partial chip region adjacent thereto are depicted herein. In some embodiments, the semiconductor substrate 100 may be a silicon substrate or another semiconductor substrate. In some other embodiments, the semiconductor substrate 100 may be a silicon wafer, so as to facilitate the wafer-level packaging process.

In some embodiments, a sensing region or device region 120 is located in the semiconductor substrate 100 in each of the chip regions 110. The sensing region or device region 120 may be adjacent to the first surface 100a of the semiconductor substrate 100.

In some embodiments, the sensing region or device region 120 comprises a sensing element. In some embodiments, the sensing region or device region 120 comprises a light-sensing element or another suitable optoelectronic element. In some other embodiments, the sensing region or device region 120 may comprise a biometrics sensing element (such as a fingerprint-recognition element) or comprise a sensing element which is configured to sense environmental characteristics (such as a temperature-sensing element, a humidity-sensing element, a pressure-sensing element or a capacitance-sensing element) or another suitable sensing element.

There is an insulating layer 130 on the first surface 100a of the semiconductor substrate 100. In general, the insulating layer 130 may be made of an interlayer dielectric (ILD) layer, inter-metal dielectric (IMD) layers and a covering passivation layer. To simplify the diagram, only a single insulating layer 130 is depicted herein. In some embodiments, the insulating layer 130 may comprise an inorganic material, such as silicon oxide, silicon nitride, silicon oxynitride, metal oxide, a combination thereof, or another suitable insulating material.

In some embodiments, one or more conducting pads 140 are located in the insulating layer 130 in each of the chip regions 110. In some embodiments, the conducting pads 140 may be a single conducting layer or comprise multiple conducting layers. To simplify the diagram, only two conducting pads 140 comprising a single conducting layer in the insulating layer 130 are depicted herein as an example. In some embodiments, the insulating layer 130 in each of the chip regions 110 comprises one or more openings exposing the corresponding conducting pads 140. In some embodiments, the sensing element in the sensing region or device region 120 may be electrically connected to the conducting pads 140 through interconnection structures (not shown) in the semiconductor substrate 100.

In some embodiments, the aforementioned structure may be fabricated by sequentially performing a front-end process and a back-end process of a semiconductor device. For example, the sensing region or device region 120 may be formed in the semiconductor substrate 100 during the front-end process. The insulating layer 130, the interconnection structures, and the conducting pads 140 may be formed on the semiconductor substrate 100 during the back-end process. In other words, the following method for forming a chip package proceeds subsequently packaging processes to the aforementioned structure after the back-end process is completed.

In some embodiments, an optical element 150 is disposed on the first surface 100a of the semiconductor substrate 100 in each of the chip regions 110. The optical element 150 corresponds to the sensing region or device region 120. In some embodiments, the optical element 150 may be a micro-lens array, a color filter layer, a combination thereof, or another suitable optical element.

In some embodiments, the semiconductor substrate 100, the insulating layer 130 and the optical element 150 together form a first substrate 160, as shown in FIG. 1A. In some embodiments, the first substrate 160 is only composed of the semiconductor substrate 100 and the insulating layer 130. In some other embodiments, the first substrate 160 may comprise other suitable elements in addition to the semiconductor substrate 100 and the insulating layer 130. In some embodiments, the first substrate 160 has an initial thickness T1 which is about 735 μm or 750 μm. In some other embodiments, the first substrate 160 may have another suitable initial thickness.

Referring to FIG. 1B, a support substrate (or a carrier substrate) 170 is attached on the front side of the first substrate 160. For example, the conducting pads 140 and the optical element 150 are adjacent to the front side of the first substrate 160. The conducting pads 140 and the optical element 150 are located between the semiconductor substrate 100 and the support substrate 170.

In some embodiments, the support substrate 170 has a thickness T2 which is about 400 μm or greater than about 400 μm. In some embodiments, the plane size (area) of the support substrate 170 is substantially the same as that of the semiconductor substrate 100. In some embodiments, the support substrate 170 comprises glass, a semiconductor material (such as silicon) or another suitable support substrate material. In some embodiments, the material of the support substrate 170 is the same as that of the semiconductor substrate 100. In some other embodiments, the material of the support substrate 170 is different from that of the semiconductor substrate 100.

In some embodiments, the support substrate 170 is attached onto the first substrate 160 by an adhesive layer 180. In some embodiments, the adhesive layer 180 comprises double-sided tape or another suitable adhesive material. Furthermore, the adhesive layer 180 may comprise a removable material. For example, the adhesive layer 180 may be formed of a material the adhesive property of which is eliminated by heat.

Referring to FIG. 1C, a thinning process using the support substrate 170 on the front side of the first substrate 160 as a carrier substrate is performed on the back side of the first substrate 160. As a result, the initial thickness T1 of the first substrate 160 is reduced.

Specifically, a thinning process is performed on the second surface 100b of the semiconductor substrate 100 which is attached with the support substrate 170. As a result, the thickness of the semiconductor substrate 100 is reduced. In some embodiments, the support substrate 170 is used to provide the first substrate 160 with support. The support substrate 170 has sufficient thickness T2 so that the thickness of the first substrate 160 can be as low as possible. In some embodiments, the thinning process comprises an etching process, a milling process, a grinding process, a polishing process or another suitable process.

In some embodiments, the thinned first substrate 160 losses about 85% of the initial thickness T1 to about 95% of the initial thickness T1. The initial thickness T1 of the first substrate 160 becomes a thickness T1′ after the thinning process. The thickness T2 of the support substrate 170 is greater than the thickness T1′ of the first substrate 160.

In some embodiments, the thickness T1′ is in a range from about 50 μm to about 150 μm. In some embodiments, the thickness T1′ is in a range from about 50 μm to about 100 μm. In some other embodiments, the thickness T1′ is less than about 50 μm. In some embodiments, the ratio of the initial thickness T1 to the thickness T1′ is in a range from about 5 to about 15. In some embodiments, the ratio of the thickness T2 to the thickness T1′ is greater than about 2. In some embodiments, the ratio of the thickness T2 to the thickness T1′ is in a range from about 2.6 to about 8.

Afterwards, the first substrate 160 and the support substrate 170 are diced along scribe lines SC between the chip regions 110, thereby forming multiple separated substructures 185, as shown in FIG. 1D. The substructures 185 are chips/dies with a carrier. The substructures 185 may be referred to as sensor chips/dies.

In some embodiments, the support substrate 170 is formed of a material that is easily diced (such as silicon). In some embodiments, the material of the support substrate 170 is the same as that of the semiconductor substrate 100 to facilitate the dicing process.

Referring to FIG. 1D, each of the substructures 185 comprises the thinned first substrate 160 and the support substrate 170 attached to the front side of the thinned first substrate 160. In some embodiments, the thickness of the substructures 185 is in a range from about 450 μm to about 550 μm. In some embodiments, the thickness of the substructures 185 is in a range from about 400 μm to about 450 μm. In some other embodiments, the thickness of the substructures 185 is greater than about 550 μm.

Referring to FIG. 1E, one of the substructures 185 is mounted on a second substrate 190 such that the second substrate 190 is on the back side of the first substrate 160. As a result, the first substrate 160 is located between the support substrate 170 and the second substrate 190. In some embodiments, the second surface 100b of the semiconductor substrate 100 is attached to the second substrate 190 by an adhesive layer (not shown). As a result, the semiconductor substrate 100 is located between the support substrate 170 and the second substrate 190.

In some embodiments, the second substrate 190 is a circuit board or another suitable component. The second substrate 190 may be a printed circuit board (PCB). Furthermore, the second substrate 190 comprises contact pads 200 adjacent to its upper surface. In some embodiments, the thickness T3 of the second substrate 190 is in a range from about 300 μm to about 400 μm. In some other embodiments, the second substrate 190 may have another suitable thickness.

During the mounting/bonding process, the adhesive layer (not shown) is formed on the substructure 185 by a dispensing process or another suitable process. The substructure 185 is then picked up and placed on the second substrate 190. Afterwards, the substructure 185 is applied with downward force so as to uniformly press and spread the adhesive layer between the substructure 185 and the second substrate 190. Since the substructure 185 has a sufficiently thick support substrate 170, the first substrate 160 can be prevented from being physically damaged during the mounting process. The first substrate 160 is effectively prevented from cracking, bending, or warping, especially when the thickness of the first substrate 160 is very low. In other words, since the substructure 185 has a sufficiently thick support substrate 170, the thickness of the first substrate 160 can be as low as possible without damaging the first substrate 160. Therefore, the size of the chip package can be reduced even further.

In addition, the support substrate 170 also prevents the first substrate 160 from being contaminated. For example, the conducting pads 140 and the optical element 150 are covered by the support substrate 170. As a result, the support substrate 170 can protect the conducting pads 140 and the optical element 150 from dust or particle contamination during various processes. Therefore, the reliability and quality of the chip package is greatly enhanced.

In accordance with some embodiments, the ratio of the thickness T2 of the support substrate 170 to the thickness T1′ of the first substrate 160 should be substantially equal to or greater than about 2. In some cases, if the ratio of the thickness T2 to the thickness T1′ is less than about 2, the first substrate 160 may likely suffer from issues such as cracking, bending, or warping. However, embodiments of the disclosure are not limited thereto. In some other cases, the ratio of the thickness T2 to the thickness T1′ may be less than about 2.

In accordance with some embodiments, the ratio of the thickness T2 of support substrate 170 to the thickness T1′ of the first substrate 160 is in a range from about 2.6 to about 8. In some cases, the ratio of the thickness T2 to the thickness T1′ should be substantially equal to or less than about 8. If the ratio of the thickness T2 to the thickness T1′ is greater than about 8, it may be difficult to cut the first substrate 160 and the support substrate 170 along the scribe lines SC. However, embodiments of the disclosure are not limited thereto. In some other cases, the ratio of the thickness T2 to the thickness T1′ may be greater than about 8.

Referring to FIG. 1F, the support substrate 170 and the adhesive layer 180 are removed from the substructure 185 on the second substrate 190. As result, the conducting pads 140 and the optical element 150 are exposed. In some embodiments, the adhesive property of the adhesive layer 180 is eliminated by heat. As result, the support substrate 170 is debonded and removed. For example, the adhesive layer 180 is heated by ultraviolet (UV) light. After the removal of the support substrate 170 and the adhesive layer 180, the thickness of the substructure 185 enters in a range from about 50 μm to about 150 μm or even less than about 50 μm.

Afterwards, multiple conducting structures 210 are formed on the second substrate 190. In some embodiments, the conducting structures 210 are wires or other suitable conducting structures. The conducting structures 210 may extend from the contact pads 200 to the conducting pads 140 by performing a wire bonding process. The conducting structures 210 electrically connect the semiconductor substrate 100 to the second substrate 190.

In some embodiments, the thickness of the chip package is extremely low. Especially, the chip package comprises the thinned first substrate 160 so that the overall height of the conducting structures 210 is reduced. The thickness T1′ of the thinned first substrate 160 is at least less than about 200 μm. For example, the thickness T1′ is in a range from about 50 μm to about 150 μm. The thickness T1′ may be less than about 50 μm. Therefore, the ratio of the thickness T3 of the second substrate 190 to the thickness T1′ is in a range from about 2 to about 8.

In accordance with some embodiments, the ratio of the thickness T3 to the thickness T1′ should be substantially equal to or greater than about 2. In some cases, if the ratio of the thickness T3 to the thickness T1′ is less than about 2, the first substrate 160 may easily suffer from issues such as cracking, bending, or warping.

In accordance with some embodiments, the ultra-thin first substrate 160 is carried by the support substrate 170 during the bonding process so that the ratio of the thickness T3 to the thickness T1′ is substantially equal to or less than about 8. In some cases, if no support substrate 170 carries the first substrate 160, the ratio of the thickness T3 to the thickness T1′ would be greater than about 8. As a result, the size of the chip package cannot be decreased. However, the ratio of the thickness T3 to the thickness T1′ is not limited thereto.

In some embodiments, the distance D1 between the second substrate 190 and the conducting pads 140 is greater than the distance D2 between the second substrate 190 and the sensing region or device region 120. One of the conducting structures 210 has an end 210a on the conducting pads 140. The distance D1 is less than the distance D3 between the second substrate 190 and the end 210a of the conducting structures 210, as shown in FIG. 1F.

In some embodiments, the distance D1 is less than about 200 μm. For example, the distance D1 is in a range from about 50 μm to about 150 μm. The distance D1 may be less than about 50 μm.

In some embodiments, the distance D2 is much less than 200 μm. For example, the distance D2 is in a range from about 25 μm to about 75 μm. The distance D2 may be less than about 25 μm.

In some embodiments, the distance D3 is at least less than about 200 μm. For example, the distance D3 is in a range from about 50 μm to about 150 μm. The distance D3 may be less than about 50 μm.

It should be realized that there are variations in exemplary embodiments according to the invention, and it is not limited to the aforementioned embodiments. For example, although the embodiments of FIGS. 1A to 1F describe a method for forming a chip package comprising an optical sensing element, embodiments of the disclosure are not limited thereto. The method for forming a chip package according to the invention can be applied to other types of chip packages.

In general, when a substrate is being thinned, the substrate is protected temporally during the thinning process only by a tape with low thickness. In order to prevent the substrate from cracking during a subsequent bonding process, the thickness of the substrate cannot become too low. As a result, the size of the chip package is limited.

According to the aforementioned embodiments, a temporary support substrate is used to provide a wafer substrate with structural strength, thereby facilitating thinning and dicing the wafer substrate and further facilitating bonding a chip substrate, which is cut from the wafer substrate, to a circuit board. Therefore, the thickness of the chip substrate is significantly reduced. As a result, the size of the chip package can be decreased even further.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a first substrate comprising a sensing region or device region; and
a second substrate, wherein the first substrate is mounted on the second substrate and is electrically connected to the second substrate, and wherein a ratio of a thickness of the first substrate to a thickness of the second substrate is in a range from 2 to 8.

2. The chip package as claimed in claim 1, wherein the thickness of the first substrate is in a range from 50 μm to 150 μm.

3. The chip package as claimed in claim 1, wherein the thickness of the second substrate is in a range from 300 μm to 400 μm.

4. The chip package as claimed in claim 1, wherein the second substrate is a circuit board.

5. The chip package as claimed in claim 1, further comprising a conducting structure, wherein the conducting structure is on the first substrate and electrically connects the first substrate to the second substrate.

6. The chip package as claimed in claim 5, wherein a distance between the second substrate and the conducting structure on the first substrate is in a range from 50 μm to 150 μm.

7. The chip package as claimed in claim 1, wherein the first substrate has a front side and a back side, and the second substrate is on the back side of the first substrate, and wherein the first substrate further comprises a conducting pad adjacent to the front side.

8. The chip package as claimed in claim 7, wherein a distance between the second substrate and the conducting pad is in a range from 50 μm to 150 μm.

9. A method for forming a chip package, comprising:
providing a first substrate comprising a sensing region or device region; and
mounting the first substrate onto a second substrate, wherein the first substrate is electrically connected to the second substrate, and wherein a ratio of a thickness of the first substrate to a thickness of the second substrate is in a range from 2 to 8.

10. The method as claimed in claim 9, wherein the thickness of the first substrate is in a range from 50 μm to 150 μm.

11. The method as claimed in claim 9, wherein the thickness of the second substrate is in a range from 300 μm to 400 μm.

12. The method as claimed in claim 9, wherein the first substrate has a front side and a back side, and the second substrate is on the back side of the first substrate, and wherein the first substrate further comprises a conducting pad adjacent to the front side.

13. The method as claimed in claim 9, wherein providing the first substrate comprises attaching a support substrate on the first substrate, and a thickness of the support substrate is greater than the thickness of the first substrate.

14. The method as claimed in claim 13, wherein a ratio of the thickness of the support substrate to the thickness of the first substrate is greater than 2.

15. The method as claimed in claim 13, wherein the support substrate comprises glass or a semiconductor material.

16. The method as claimed in claim 13, wherein providing the first substrate further comprises performing a thinning process on the first substrate attached with the support substrate to obtain the thickness of the first substrate.

17. The method as claimed in claim 16, wherein the first substrate has an initial thickness before the thinning process, and a ratio of the initial thickness to the thickness of the first substrate is in a range from 5 to 15.

18. The method as claimed in claim 13, wherein providing the first substrate further comprises performing a dicing process on the first substrate and the support substrate.

19. The method as claimed in claim 13, wherein mounting the first substrate onto the second substrate comprises mounting the first substrate attached with the support substrate onto the second substrate, and wherein the first substrate is between the support substrate and the second substrate.

20. The method as claimed in claim 19, further comprising removing the support substrate after mounting the first substrate attached with the support substrate onto the second substrate.
